(19) United States
(12) Patent Application Publication
(10) Pub. No.: US 2023/0065012 A1
(43) Pub. Date: Mar. 2, 2023

(54) BUILDING PROJECT MANAGEMENT VALIDATION PRODUCT

(71) Applicant: Oren Melamed, Tzur Hadassah (IL)

(72) Inventors: Oren MELAMED, Tzur Hadassah (IL); Vitali Minin, Tzur Hadassah (IL)

(21) Appl. No.: 17/412,382

(22) Filed: Aug. 26, 2021

(51) Int. Cl. G06Q 10/08; G06Q 50/08; G06Q 10/06; G06Q 30/02; G06F 9/451

(52) U.S. Cl. CPC G06Q 10/0875; G06Q 50/08; G06Q 10/06313; G06Q 30/0283; G06F 9/451

(57) ABSTRACT

A system for monitoring a construction project: a processor; a memory; and a GUI, a hierarchical legend including: a list of articles, each article having a unique name which is used in a corresponding construction drawing associated the hierarchical legend; each the article having at least one subset article with a respective the unique name; each subset article having either none, one or more than one subset articles a respective unique name; a list of quantities corresponding to the list of articles, and wherein the quantities are calculated by extracting from the construction drawing, for each article, a measurement for the article of construction drawn on the construction drawing and converting the measurement of the article of construction to a quantity of units thereof; and a price per terminal article.

### FIELD OF THE INVENTION

The present invention relates to an urban planning computer system and, more particularly, to a method and system for managing infrastructure and construction projects and overseeing the execution of an infrastructure or construction project.

### BACKGROUND OF THE INVENTION

As a first step in a project the commissioner of the project appoints a project manager. The project manager appoints consultants \ planners in relevant fields.

Each planner is required to prepare a preliminary design for the infrastructure aspect under their purview. The planner usually generates drawings in AutoCAD® software that includes locations and dimensions and quantities of all elements (water junctions, electricity boxes and lines, sanitation paths etc.). Each type (water, electric, sanitation etc.) of design is a separate file. Each type of element is defined as a separate layer in the file. Once the plan is complete, a PDF file (usually) is generated and sent to the project manager for review.

As part of the project, the planner is required to prepare a Bill of Quantity. A Bill of Quantity is a document that lists all elements that exist in the design files with the measurements, length, area etc., of those elements (e.g., length of piping, amount of cable, etc.). The Bill of Quantity (BoQ or simply BQ) is generated on the basis of a price list that was defined the entity that commissioned the project (hereafter ‘Commissioner’). The project cost is estimated based on the BQs of the planners. The quantities may be measured in number, area, volume, weight or time.

The bill of quantities is issued to tenderers for them to prepare a price for carrying out the construction work. The bill of quantities assists tenderers in the calculation of construction costs for their tender, and, as it means all tendering contractors will be pricing the same quantities (rather than taking-off quantities from the drawings and specifications themselves), it also provides a fair and accurate system for tendering.

Today the BQ is prepared with the help of various software packages that allow the planner to take a predefined price list and add quantities, length, area etc. to each item. The resulting document is a long list of items which is called the BQ.

The only way to check that the BQ actually matches the files of the plans (usually created using the expensive software such as AutoCAD® and the like) is to go through the list of the BQ item by item and compare the item to the relevant layer in a planning file.

Seeing as the only way to measure the length, area, or amount of any element within a design file is with the help of the design software, a project manager would need to purchase the software and know how to operate it. Moreover, even if the project manager has the software and knows how to run it, it will still be a laborious and time-consuming task to check each and every layer of the planning file against each section of the price list. As a result, the planning file is not usually checked!

One existing solution is to outsource the checking to a third party or to hire an expert in the field of quantity estimation (a quantity surveyor). However, the common practice is to manually measure (yes, measuring by hand) the lines on a paper copy of the drawing/plan. Such an exercise is fraught with mistakes and inaccuracies leading to incorrect quantity estimates and, as a result, an incorrect cost estimate for the entire project.

This problem is well known to all the parties. As a result, each party adds a margin to the estimate, to cover the inaccuracy. This margin is often called a contingency sum. The planner adds a small margin, the project manager adds a small margin, and the commissioner adds a small margin before making the tender public.

This creates a situation where the infrastructure and construction projects are priced much higher than required. In addition, seeing as each planner in his/her field produces a separate plan, there are situations where different designs conflict with each other without the planners' knowledge, which creates many problems once the tender has gone public and the work has started.

At present, there is no technological tool to compare the design files of the various planners and warn of such conflicts. One of the tools available on the market are ARCGIS ONLINE GIS software that allows planners to upload the design files and view all design layers. However, each layer recognition and cross-checking of that layer is performed individually, which requires extracting data from each layer individually. This is a lengthy and cumbersome process which is completed by manually summarizing the data in order to get the overall estimate.

Additionally, each planner names the design layers differently, which makes it difficult for the project manager to quickly identify the layers and is required to work against a legend/key of each file, where the key/legend varies from planner to planner.

### SUMMARY OF THE INVENTION

According to the present invention there is provided a system for monitoring a construction project, the system including: a processor; a non-transient memory with computer-readable instructions stored thereon; and a graphical user interface (GUI) controlled by the processor according to the computer-readable instructions, the GUI adapted to display a hierarchical legend including: a list of articles, each article of the list having a unique name which is used in a construction drawing associated the hierarchical legend to indicate an article of construction represented in the construction drawing corresponding to the unique name; each the article having at least one subset article, each the subset article having a respective the unique name; each subset article having either none, one or more than one subset articles, each with a respective the unique name; a list of quantities corresponding to the list of articles, and wherein the quantities are calculated by extracting from the construction drawing, for each the article or the subset article, a measurement for the article of construction drawn on the construction drawing, wherein the article of construction is indicated by a respective the name of the respective article or subset article and converting the measurement of the article of construction to a quantity of units thereof; and a price per subset article for each the subset article without a subset article of its own.

According to further features in preferred embodiments of the invention described below the system further includes a selectable price estimate per article of the list of articles.

According to still further features the selectable price estimate displayed in the GUI includes an estimate selected from a group including a highest price, a lowest price and an average price, wherein the highest price is a the price per subset article of a highest priced subset article of the article, wherein the lowest price is a the price per subset article of a lowest priced subset article of the article, and wherein the average price is an average of all prices of the subset articles of the article.

According to still further features the measurement for the article of construction is selected from the group including: a length, a size of an area, and a number of pieces.

According to still further features a name for a specific the article of construction in the construction drawing is changeable to conform to a given the unique name of a corresponding the article or subset article in the list of articles.

According to still further features a given the unique name of a specific the article or subset article in the list of articles is changeable to conform to a corresponding the article of construction in the construction drawing.

According to another embodiment there is provided a method for providing a set of rules for validating construction and infrastructure plans, including: generating a set of rules for validating computer-readable project plans having distinct layers representing articles of construction positioned in specific locations; receiving one of the project plans in the system; comparing each layer to one or more rules specified for layer types of the respective layer; and outputting an allowed or rejected feedback including a reason for the feedback.

According to further features in the described preferred embodiments one of the rules for the layer types is a geometry type specified for the articles of construction in a given layer.

According to still further features one of the rules for the layer types is that a first specified layer type is not allowed to include the articles of construction of the first specified layer type in a same location as articles of construction of a second specified later type.

According to another embodiment there is provided a method for calculating a price from a construction drawing, the method including: providing a graphic user interface (GUI) and associated system for converting the construction drawing into a list of articles with quantities assigned to each of the articles; receiving the construction drawing at the system; extracting from the construction drawing, for each article of the list of articles, a measurement of an indicator of the respective article, where the indicator is drawn on the construction drawing, wherein the measurement is converted into a quantity of units of the article; displaying on the GUI the list of articles and a corresponding the quantity of units; and receiving an offset factor from a user in a field in the GUI provided therefor; and calculating a price per each the article based on a price per unit, the quantity of units and the offset factor.

According to further features, the measurement of the indicator is selected from the group including: a length, an area, and a number of pieces. According to still further features, the offset factor is indicative of a depth of a given the area thereby converting the given area into a volume. According to still further features, the offset factor is indicative of a cushioning factor for the quantity of units. According to still further features, the offset factor is indicative of a multiplicity of a subset article of a given the article.

According to still further features, the method further includes receiving a bill of quantities; comparing each quantity in the bill of quantities with each of the quantity of units for a corresponding the article; and outputting on the GUI a delta value between each the quantity in the bill of quantities and each respective the quantity of units.

According to still further features, the hierarchical legend further includes: an interface for creating a compound article with selected sub-elements nested thereunder; and wherein said hierarchical legend generates a special name for each of said sub-elements.

### BRIEF DESCRIPTION OF THE DRAWINGS

Various embodiments are herein described, by way of example only, with reference to the accompanying drawings, wherein:

FIG. 1 is a high-level diagram of the instant system 100 and exemplary file inputs used by the monitoring system;

FIG. 2A-B are exemplary screen shots of a hierarchical legend 200 implemented on a GUI;

FIG. 3 is a screen shot of an exemplary estimate screen 300 of the GUI;

FIG. 4 is a screen shot of a comparison screen 400 of the instant GUI;

FIG. 5 is a flow chart of the steps of the process 500;

FIG. 6 is a flow chart of the process 600 for validating a planning file;

FIG. 7 is a screen shot of compound article name generation screen.

### DESCRIPTION OF THE PREFERRED EMBODIMENTS

The principles and operation of a project management system and graphical user interface (GUI) according to the present invention may be better understood with reference to the drawings and the accompanying description.

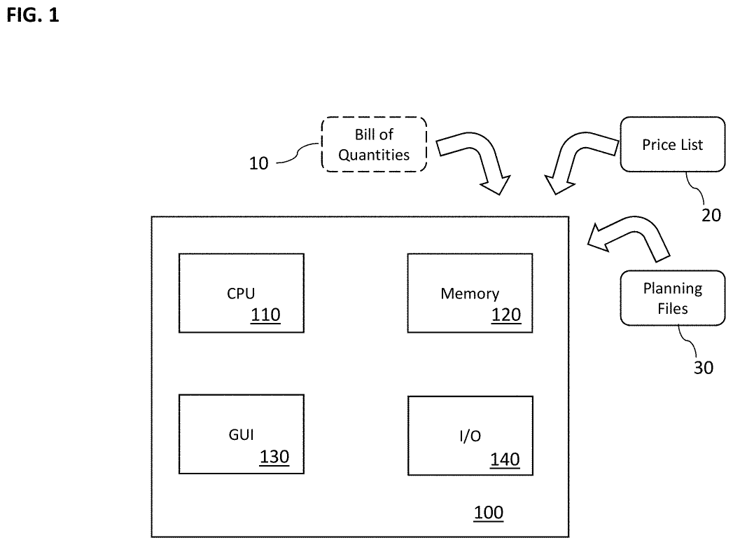

Referring now to the drawings, FIG. 1 illustrates a high-level diagram of the instant system 100 and exemplary file inputs used by the monitoring system. A system 100 is provided for monitoring a construction project where the system includes a processor (CPU) 110, a non-transient memory 120 with computer-readable instructions stored thereon; and a graphical user interface (GUI) 130 controlled by the processor according to the computer-readable instructions. Only very basic, high-level components germane to the innovative system are disclosed here. It is clear that computing systems of this type are well known in the art.

The system is configured to receive digital computer files from external sources as well as input via a human input device (HID) such as a keyboard and/or mouse etc. A general Input/Output module 140 is designated to represent the one or more components of the system that handle input from HIDs or and/or via an Internet connection from a remote location. The I/O module also represents the component or components that transfer visual data from the GUI to a peripheral such as a display screen and the like. It is also made clear that the system may be hosted on a server (or in a cloud) and displayed on an end-user device having appropriate software installed thereon.

Hierarchical Legend

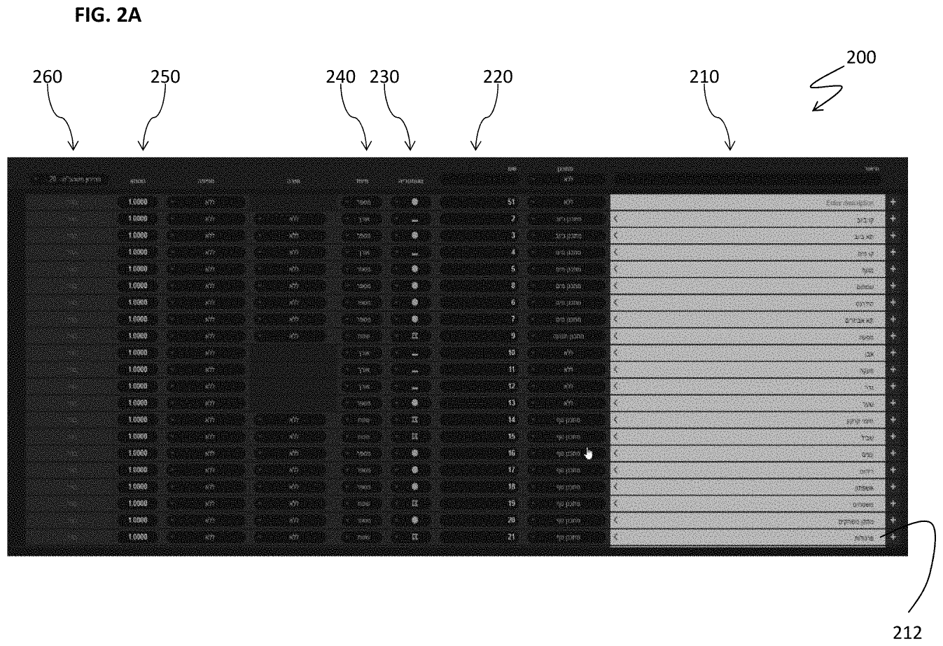

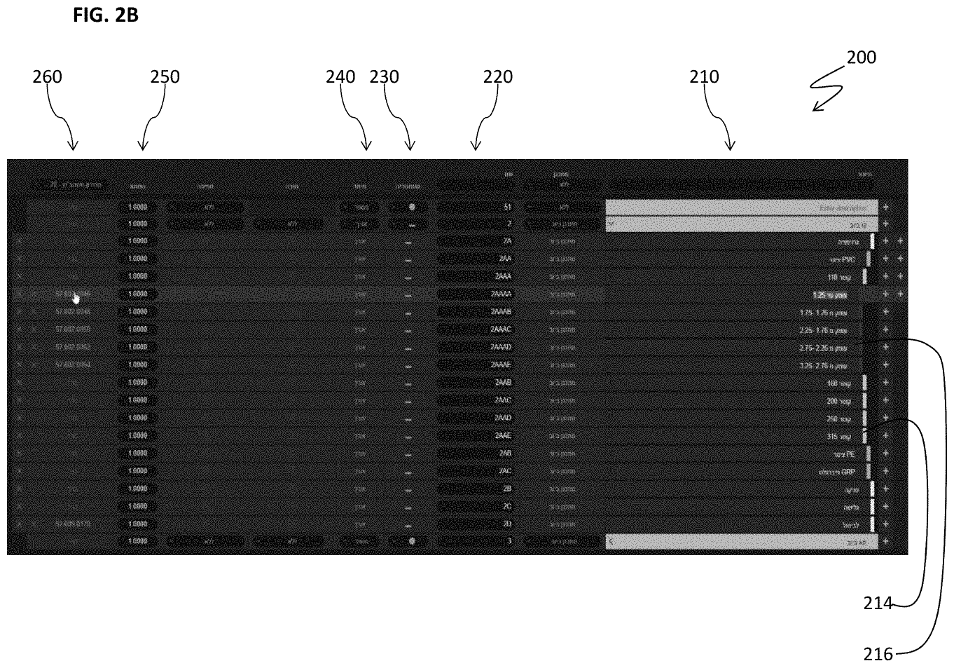

One of the innovative features of the instant system is the Hierarchical Legend. FIG. 2A depicts an exemplary screen shot of a hierarchical legend 200 implemented on a GUI, with the articles not expanded. FIG. 2B depicts the exemplary screen shot 200 of a hierarchical legend implemented on a GUI, with one of the articles partially expanded. The hierarchical legend includes a list of articles 210, where each article has legend or key describing the article. Each article (and subset article) has a unique name 220. These names are actually used or intended to be used in the construction drawing or drawings that are associated with the hierarchical legend to indicate that a particular article of construction (tree, drainage pipe, asphalt etc.) represented in the construction drawing (as a geometric shape) corresponds to the unique name.

For each article there is a designated geometry 230 by which the articles of construction need to be drawn in the corresponding layer in the construction drawing. The geometry is either a line, a polygon or a dot. Each type of geometry has a correlating measurement type 240. A line (or polyline) is measured in length, a polygon is measure in area and a dot is measured in number. Each layer has an offset factor 250 which is discussed elsewhere herein.

The files include layers of drawings. Each layer is for a different article of construction. The article of construction may be a regular article or a compound article. A regular article is an element that is priced by itself (this is almost always a subset article, s discussed below). A compound article is an element which is made up of a number of sub-elements, each of which is priced separately. For example, there may be one layer for roads and another layer for trees. A road is an example of a compound article as it is made up sub-elements such as layers of sand, gravel, stone and asphalt. Each of these sub-elements is priced separately so it is necessary to details each sub-element.

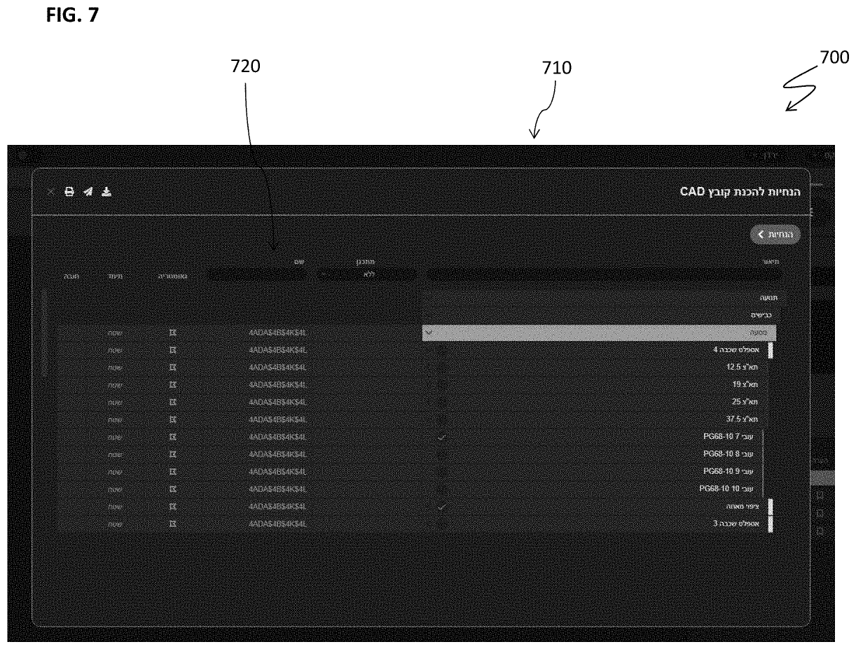

FIG. 7 is a screen shot of compound article name generation screen 700. The GUI has a column 710 with a description of the compound articles and the sub-elements of the article. Innovatively, the hierarchical legend further includes an interface for creating a compound article with selected sub-elements nested thereunder. The user can create a compound article will all the sub-elements, down to the last detail.

Innovatively, the system of the hierarchical legend generates a special name for each sub-element which appears in the name column 720. No legacy system generates a new name for an article or element. Here, the user specifies all the elements of a compound article and the system generates a special new name for each element. These special names can be used in a construction drawing created with the hierarchical legend or for adjusting a drawing created with a different legend to conform to the hierarchical legend.

Whether regular or compound, each article is built in the same nested fashion. There are three types of legends, a primary article 212, a subset article 214 and a terminal article 216. The primary article is at the “root” of every tree (these trees are inverted, as is well known). A subset article is any article that is nested under another article. There are subset articles of primary articles and subset articles of subset articles. A terminal article is an article or subset article that has no subset article underneath it. Terminal articles 216 have a price per unit 260. Other articles do not include a price. At most, a non-terminal article can have a highest, lowest and average estimate.

At present, it is widespread practice for each planner to use their own naming system for each article of construction. Legends do exist but are generally not followed. Aside from that fact, the legends themselves are “flat” or one-dimensional. The legend (key) defines the data of each design layer such as name, geometry, measurement units, etc. The problem with the “flat”/one-dimensional legend is that plans go through different stages, and in early stages, the planner does not have (either did not receive or did not create) a detailed plan and therefore is unable to define the layers according to the specific subset. For example, there is a design layer that represents sewage pipes: sewerage pipes can be made from different materials, have different diameters, be laid at different depths etc. If the planner knows the exact data of the specific pipeline (e.g. sewage pipe, PVC material, diameter 10″, laid at a depth of 2 m) then the planner can associate the specific pipeline with a specific sub-section of the legend. However, if the planner does not have the particular specifications of the pipe then s/he cannot associate it with the correct sub-section (but rather just put it under the general “sewerage pipe” section) and as such, the pipeline cannot be defined according to the legend and the particular layer cannot be properly associated with the price in the price estimate. Early-stage plans are not usually detailed to such a level.

No system exists, until now, that provides a hierarchical legend as disclosed herein. Each project may have a hierarchical legend that is specific to that project. Ultimately, however, the preferred situation is that a single hierarchical legend is used for all projects as a standard.

A hierarchical legend as referred to herein is built like a logic tree and includes a list of common articles each having a unique name. Each article further has a subset of one or more articles nested under it. These nested articles are referred to herein as subset articles. The subset articles may themselves have subset articles nested under them. Any article that is a nested article is referred to herein as subset article even though it may be a sub-subset of the primary article or a sub-sub-subset or even further removed from the primary article.

For example, in the hierarchical legend there may be a data field or category “sewer pipe” (this may be referred to herein as an “article” or primary article), within this field there are nested fields or sub-categories (subsets) that define other particulars, for example, the optional pipe materials (e.g. PVC, PE, metal, etc.; these are all subset articles), and within each of the different options there is a list of different diameters (subset articles of subset articles), and so on until you reach a full definition of the product.

Each article and subset article has a unique name. This arrangement is innovative and allows various features and functionality (some of which are discussed below in detail) which heretofore was not available for monitoring construction projects.

Ideally, each planning file, layer and article of construction is created using the hierarchical legend. In such cases, there is an exact conformity between the construction drawings (the term used herein for construction plans generated using the drawing software discussed elsewhere) and the legend. However, in most cases the names of the layers and/or articles of construction do not conform to the names in the hierarchical legend. In such cases either the names in the drawings are changed to conform with the legend or the names in the legend are changed to conform with the names used in the construction drawings.

The hierarchical legend interfaces with another data source which is the price list 20 (see FIG. 1). The price list assigns price for specific articles of construction. Essentially, prices are only assigned to ‘fruit’ at the ends of the logic tree, i.e., subset articles that have no additional subset articles below them. These articles are also referred to herein as terminal articles. In one of the examples above, a metal sewerage pipe (which is a subset article) is not assigned a price; but a metal sewerage pipe with a 10″ diameter to be laid at 2 m depth will have a price. Said another way, there is provided, by the price list, a price per subset article for each subset article without a subset article of its own.

The hierarchical legend allows the planner to associate the layer with each stage of the hierarchy, even if s/he does not know the full data for the product. For example, the planner can associate the layer of the plan with the data field “PVC pipe” even if they do not know the diameter of the pipe or the depth at which the pipe will be laid.

Because all the latter sub-categories (deeper nested fields, i.e., terminal articles) are associated with the price list, the software can calculate the minimum, maximum and the average prices, by selecting the highest priced subset article in a category, a lowest priced subset article in that category and by calculating an average of all the options that are nested below the selected category within the hierarchical legend.

A price estimate for the entire project, according to quantities (discussed below) is calculated based on the minimum, maximum and average potential price per category (article in the list of articles or primary article). The selectable price estimate displayed in the GUI includes an estimate selected from a group including a highest price, a lowest price and an average price. The highest price is a price per subset article of a highest priced subset article of a given article/category. The lowest price is a price per subset article of a lowest priced subset article of that primary article/category. The average price is an average of all prices of the subset articles for that article/primary article/category.

When the system calculates these estimates, it provides a true upper and lower parameter and average price for the project cost as opposed to the present method of guessing and padding estimates due to uncertainty (see Background above). Therefore, even at an early stage in the project where the plans do not have detailed specifications, the tenderers are able to provide realistic price proposals based on calculations, not guesswork.

Once there is a correlation between the hierarchical legend and the construction drawing then the system can function optimally. The instant system receives at least one planning file 30 (see FIG. 1) which is generated by a drawing software and includes a construction drawing. Such drawings can be generated on dedicated software known in the art. In some embodiments, the instant system includes a module of software for creating such files. In such embodiments, the planning files 30 may be generated on the same device or network as the monitoring system, and in some cases even integrated therewith. Usually, planning files are prepared by planners as discussed above. More than one planning file can (and usually does) belong to a single construction project.

Quantities

Exemplarily, the GUI has a screen for price estimates. The price estimate for a specific article in a given project is made up of a price per unit and a quantity of unit. The system multiplies the number of units by the price per unit to return a cost of all the unit of that article. The number of units needs to be known and the price per unit needs to be known. As discussed elsewhere, the price per unit is provided as an input to the system as price list 20 (see. FIG. 1), usually in the form of a digital file.

The quantities of each of the articles of construction can be provided as Bill of Quantities (BQ) by a surveyor of quantities, depicted as BQ 10 in FIG. 1. However, this method is optional in the instant system and therefore depicted by a broken line. Innovatively, the instant system generates quantities per terminal article by extracting these quantities from the construction drawings, as opposed to receiving these quantities as an input file (such as a digital file).

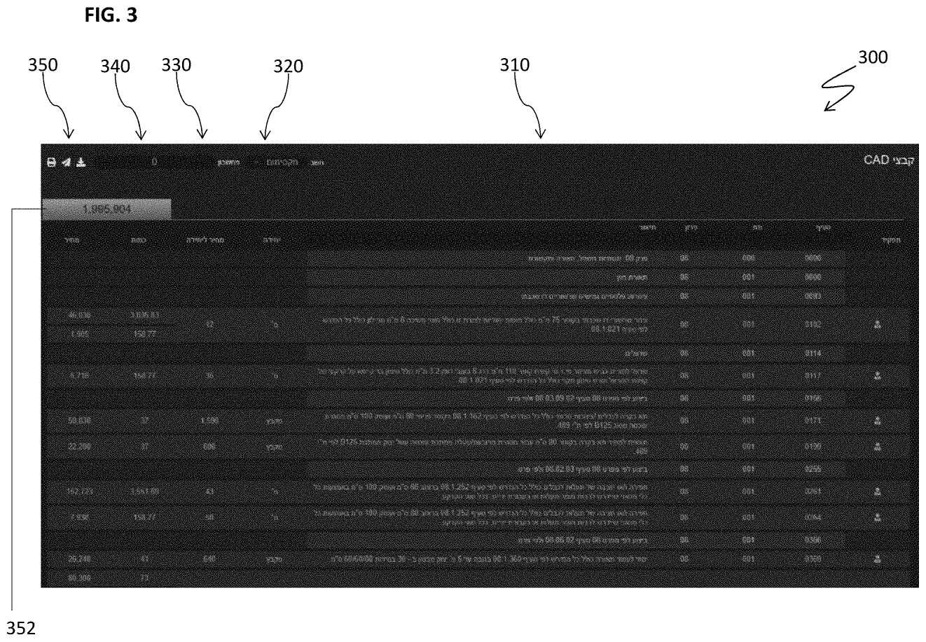

FIG. 3 depicts a screen shot of an exemplary estimate screen 300 of the GUI. The estimate screen has a column with a description of the article of construction 310 which is essentially a terminal article from the hierarchical legend. Another column includes the type of unit 320 such as individual unit, group, meter, kilometer, square meter etc. There is also a column for price per unit 330, a quantity column 340 and the calculated price (quantity multiplied by price per unit) column 350.

For the estimate to be correct, the construction drawing has to be converted into a list of quantities that corresponds to the list of articles in the hierarchical legend. This is a BQ that is generated by the innovative system. The quantities are calculated by extracting a measurement (length, size of an area or number of pieces) of each article of construction or indicator drawn on the construction drawing and associating that measurement to the corresponding article or subset article in the legend.

Each article of construction or indicator shown on the drawing is identified by a respective name of the respective article or subset article, i.e., according to the legend of the hierarchical legend. The system converts the measurement for each article of construction/indicator into a quantity of units for the corresponding article.

As detailed above, each layer must be built according to the geometry 230 defined in the key/legend and is either a dot, a polyline or closed polyline, i.e., a polygon. Each article of construction or indicator has a measurement type 240 which is either a length (polyline or simply “line”), [a size of] an area (polygon) or a number of pieces (dot). For example, a tree or streetlight may be represented by a dot, a street may be represented by a line and a park may be represented by a polygon.

The legend has rules for each article regarding how to convert the measurement (length, area, number) into a unit of that article (actually most times it is a subset article). The quantity of units coupled to the price per unit gives a cost for that article. All the costs together make up the project estimate 352 and eventually the actual project cost (or thereabouts).

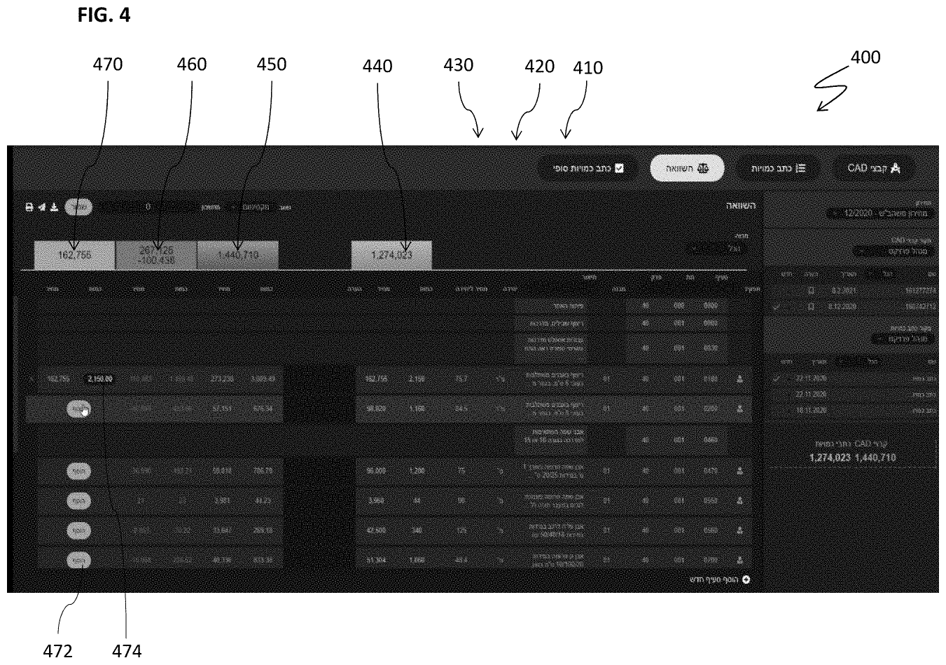

At times, a BQ has been prepared manually and a user wishes to compare the manual BQ (received in the form of a BQ 10 input) with an automatically generated BQ of the instant system. FIG. 4 is a screen shot of a comparison screen 400 of the instant GUI. One column a column with a description of the article of construction 410. Here too there are columns for type of unit 420 and price per unit 430. Innovatively, the system compares a manually prepared BQ 440 (including the number of units and calculated cost) to the list of quantities 450 (and calculated cost) automatically generated from the construction drawing showing the difference between the values in a comparison column 460. The comparison column is where one can clearly see the difference between a manually generated BQ and the quantities that are actually extracted from the planning files. The GUI includes a select column 470 with buttons 472 for selecting the manual amount 474, which is something a project manager can decide to do for whatever reason. This amount can even be manually changed to a different amount.

It may seem strange that the manual BQ does not precisely match the construction drawing when both of these are sometimes provided by the same person. However, in practice, an architect who draws a construction drawing does not spend hours measuring and counting artifacts in the drawings. This practice is usually outsourced to companies that provide such a service. Yet, as mentioned above, these companies attempt to do the measuring manually (e.g., take a piece of string and measure a drawing of a pipeline [!!]) and/or need to measure each and every layer separately. This is either not down, but rather estimated, or it is done inaccurately as people are not machines and they make mistakes with such minute and detailed work.

Offset/Conversion

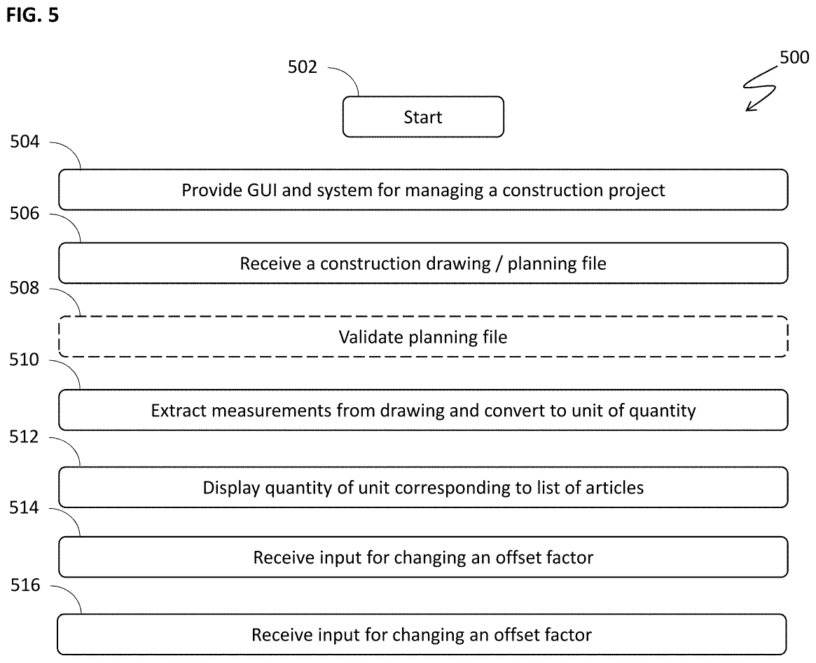

The present innovation includes a system and method for calculating a price from a construction drawing. FIG. 5 is a flow chart of the steps of the process 500. At step 502 the process begins. Step 504 includes providing a graphic user interface (GUI) and associated system for converting the construction drawing into a list of articles with quantities assigned to each of the articles as discussed above.

In step 506 (not necessarily a sequential step) the system receives the construction drawing. In an optional but preferred step 508 the system validates the construction drawing. This validation step is discussed elsewhere herein in further detail. In a subsequent step 510, the system extracts a measurement of an indicator of a respective article from the construction drawing, for each article of the list of articles. Each indicator is drawn on the construction drawing. The measurement of the indicator is converted into a quantity of units of the corresponding article with the same name.

In a next step 512, the list of articles and a corresponding quantity of units is displayed on the GUI. Innovatively, the system, in another step 514, receives an offset factor 250 (see FIG. 2A, B) in a field of the GUI provided for the same.

The cost can be altered by an offset factor which adjusts the quantity of units. The default value of the offset factor is set to 1, such that without receiving an adjustment, the offset factor has no impact on the resulting cost. However, the user can adjust the offset factor manually for any number of reasons. Three common examples of reasons are provided below.

Finally, in step 516, the system calculates a cost for each article based on a price per unit, the quantity of units and the offset factor. The quantity is multiplied by the offset factor and the resulting value is multiplied by the price per unit to receive a total price for all the articles of this type.

The measurement of the indicator is in one of three forms, depending on the geometry of the layer in the drawing: a length, an area, and a number of pieces. The offset factor can be indicative of a depth of a given area thereby converting the given area into a volume. For example, as mentioned above, a road is made up layers such as sand, gravel and/or stone, which lie beneath the asphalt. Asphalt is measured in area, e.g., 1000 meters squared, however, below the asphalt is one or more layers of preparation (sand or gravel) that have a depth, e.g., 40 cm depth. The preparation is priced in volume, not area, so the measurement of area needs to be converted into a measurement of volume (area multiplied by depth). The offset factor is used to convert this area measurement into a volume measurement.

In another application of the offset factor, the offset factor is indicative of a cushioning factor for quantity of units. In another application, the offset factor is indicative of a number of sub-elements of a given article. For example, in the layer of the plans (construction drawing) for streetlights, each dot represents a streetlight. In the corresponding legend in the hierarchical legend of the system, streetlights are divided into a number of different elements such as: a base for a 4 meter light; nested under that option is a 4 meter pole; nested under that option are three other sub-options: one arm, two arms, and three arms, each having an option of a light element (bulb, lamp). The light element has the same name in the legend but for the option of two arms, the offset factor is set to 2, because a streetlight with two arms needs two light elements. For the option of three arms, the offset factor is three.

Validation

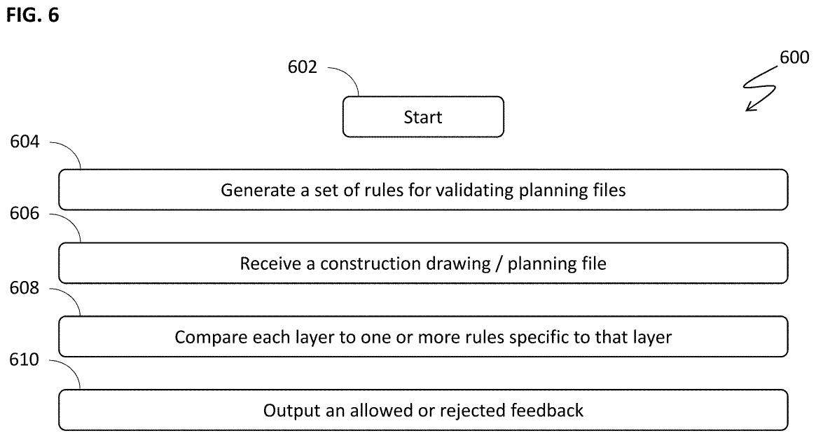

One of the features afforded by the instant hierarchical legend is a method and system for validation of planning files 30. There is provided a system and method for providing a set of rules for validating construction plans. FIG. 6 depicts a flow chart of the process 600 for validating a planning file 30.

The process starts at step 602. At step 604 a set of rules is generated. The rules are for validating computer-readable project plans having distinct layers representing articles of construction positioned in specific locations. These rules can be updated as the administrators work out more and more ways to prevent on-site problems from happening, already at the planning stage.

In step 606, the system receives a project plan. In a subsequent step 608, the system compares each layer to one or more rules specified for layer types of the respective layer. In step 610, the system outputs an allowed or rejected feedback including a reason for the feedback.

Examples of rules can be that a given layer has to be drawn with a particular geometry. If the geometry is incorrect for this layer, the entire file is rejected with the explanation and the planner needs to go back and correct the geometry of the layer. Another rule may be that certain layers are not allowed to overlap. For example, a tree layer is not allowed to overlap with a road layer. Since these layers ay be prepared by different planners, this type of overlap will be rejected.

In preferred embodiments, the system is configured to convert construction drawings into shapes that can be integrated into a geographic information system (GIS). The plans can be implemented into the destined location on a map, opening up many location-based features that the system can provide.

While the invention has been described with respect to a limited number of embodiments, it will be appreciated that many variations, modifications and other applications of the invention may be made. Therefore, the claimed invention as recited in the claims that follow is not limited to the embodiments described herein.

What is claimed is:

1. A system for monitoring a construction project, the system comprising:
a processor;
a non-transient memory with computer-readable instructions stored thereon; and
a graphical user interface (GUI) controlled by said processor according to said computer-readable instructions, the GUI adapted to display a hierarchical legend including:
a list of articles, each article of said list having a unique name which is used in a construction drawing associated said hierarchical legend to indicate an article of construction represented in said construction drawing corresponding to said unique name;
each said article having at least one subset article, each said subset article having a respective said unique name;
each subset article having either none, one or more than one subset articles, each with a respective said unique name;
a list of quantities corresponding to said list of articles, and wherein said quantities are calculated by extracting from said construction drawing, for each said article or said subset article, a measurement for said article of construction drawn on said construction drawing, wherein said article of construction is indicated by a respective said name of said respective article or subset article and converting said measurement of said article of construction to a quantity of units thereof; and
a price per subset article for each said subset article without a subset article of its own.

2. The system of claim 1, further comprising a selectable price estimate per article of said list of articles.

3. The system of claim 2, wherein said selectable price estimate displayed in said GUI includes an estimate selected from a group including a highest price, a lowest price and an average price,
wherein said highest price is a said price per subset article of a highest priced subset article of said article,
wherein said lowest price is a said price per subset article of a lowest priced subset article of said article, and
wherein said average price is an average of all prices of said subset articles of said article.

4. The system of claim 1, wherein said measurement for said article of construction is selected from the group including: a length, a size of an area, and a number of pieces.

5. The system of claim 1, wherein a name for a specific said article of construction in said construction drawing is changeable to conform to a given said unique name of a corresponding said article or subset article in said list of articles.

6. The system of claim 1, wherein a given said unique name of a specific said article or subset article in said list of articles is changeable to conform to a corresponding said article of construction in said construction drawing.

7. A method for providing a set of rules for validating construction and infrastructure plans, comprising:
generating a set of rules for validating computer-readable project plans having distinct layers representing articles of construction positioned in specific locations;
receiving one of said project plans in the system;
comparing each layer to one or more rules specified for layer types of said respective layer; and
outputting an allowed or rejected feedback including a reason for said feedback.

8. The method of claim 7, wherein one of said rules for said layer types is a geometry type specified for said articles of construction in a given layer.

9. The method of claim 7, wherein one of said rules for said layer types is that a first specified layer type is not allowed to include said articles of construction of said first specified layer type in a same location as articles of construction of a second specified later type.

10. A method for calculating a price from a construction drawing, the method comprising:
providing a graphic user interface (GUI) and associated system for converting the construction drawing into a list of articles with quantities assigned to each of said articles;
receiving the construction drawing at said system;
extracting from the construction drawing, for each article of said list of articles, a measurement of an indicator of said respective article, where said indicator is drawn on the construction drawing, wherein said measurement is converted into a quantity of units of said article;
displaying on said GUI said list of articles and a corresponding said quantity of units;
receiving an offset factor from a user in a field in said GUI provided therefor; and
calculating a price per each said article based on a price per unit, said quantity of units and said offset factor.

11. The method of 10, wherein said measurement of said indicator is selected from the group including: a length, an area, and a number of pieces.

12. The method of claim 11, wherein said offset factor is indicative of a depth of a given said area thereby converting said given area into a volume.

13. The method of claim 10, wherein said offset factor is indicative of a cushioning factor for said quantity of units.

14. The method of claim 10, wherein said offset factor is indicative of a multiplicity of a subset article of a given said article.

15. The method of claim 10, further comprising:
receiving a bill of quantities;
comparing each quantity in said bill of quantities with each of said quantity of units for a corresponding said article; and
outputting on said GUI a delta value between each said quantity in said bill of quantities and each respective said quantity of units.

16. The system of claim 1, wherein said hierarchical legend further includes:
an interface for creating a compound article with selected sub-elements nested thereunder; and wherein said hierarchical legend generates a special name for each of said sub-elements.
